(19) United States
(12) Patent Application Publication
(10) Pub. No.: US 2025/0075312 A1
(43) Pub. Date: Mar. 6, 2025

(54) SEPARATOR PROCESSING DEVICE FOR ELECTROCHEMICAL APPARATUS AND SPUTTERING TARGET

(71) Applicants: Hyundai Motor Company, Seoul (KR); Kia Corporation, Seoul (KR)

(72) Inventors: Yeon Soo Kim, Gyeonggi-do (KR); Young June Park, Gyeonggi-do (KR); Jeong Soo Kim, Seoul (KR); Ji Han Lee, Gyeonggi-do (KR); Seong Un Lim, Gyeonggi-do (KR)

(21) Appl. No.: 18/535,603

(22) Filed: Dec. 11, 2023

(30) Foreign Application Priority Data
Sep. 4, 2023 (KR) 10-2023-0117179

(51) Int. Cl. C23C 14/54; C23C 14/34

(52) U.S. Cl. CPC C23C 14/54; C23C 14/3414; C25B 13/00

(57) ABSTRACT

Provided is a separator processing device for an electrochemical apparatus, the separator processing device including a vacuum chamber, a susceptor provided in the vacuum chamber and configured to allow a separator to be seated thereon, and a sputtering target provided on the vacuum chamber and including target elements and luminescent elements that are to be deposited on the separator, thereby obtaining an advantageous effect of accurately detecting the lifespan of the sputtering target and the timing of replacement of the sputtering target.

### CROSS-REFERENCE TO RELATED APPLICATION

This application claims under 35 U.S.C. § 119(a) the benefit of Korean Patent Application No. 10-2023-0117179 filed in the Korean Intellectual Property Office on Sep. 4, 2023, the entire contents of which are incorporated herein by reference.

### BACKGROUND

### Technical Field

Embodiments of the present disclosure relate to a sputtering target and a separator processing device for an electrochemical apparatus, which is capable of improving stability and reliability and accurately detecting the lifespan of the sputtering target and the timing of replacement of the sputtering target.

### Background

There is a consistently increasing need for research and development on alternative energy to cope with global warming and depletion of fossil fuel. Hydrogen energy is attracting attention as a practical solution for solving environment and energy issues.

In particular, because hydrogen has high energy density and properties suitable for application in a grid-scale, hydrogen is in the limelight as a future energy carrier.

A water electrolysis stack, which is one of electrochemical apparatuses, refers to a device that produces hydrogen and oxygen by electrochemically decomposing water. The water electrolysis stack may be configured by stacking several tens or several hundreds of water electrolysis cells (unit cells) in series.

A membrane-electrode assembly (MEA) is positioned at an innermost side of the unit cell of the water electrolysis stack. The membrane-electrode assembly includes a perfluorinated sulfonic acid ionomer-based electrolyte membrane capable of moving hydrogen ions (protons), and an anode electrode and a cathode electrode respectively disposed on two opposite surfaces of the electrolyte membrane.

In addition, a porous transport layer (PTL), a gas diffusion layer (GDL), and a gasket may be stacked on each of the outer portions (outer surfaces) of the membrane-electrode assembly (MEA) on which the anode and the cathode are positioned. A separator (or bipolar plate) may be disposed on an outer side (outer surface) of the porous transport layer (PTL) and the gas diffusion layer (GDL). The separator includes flow paths (flow fields) through which a reactant, a coolant, and a product produced by a reaction flow, or the separator may include a structure that may be substituted for the flow paths.

### SUMMARY

The present disclosure has been made in an effort to provide a sputtering target and a separator processing device for an electrochemical apparatus, which is capable of improving stability and reliability and accurately detecting the lifespan of the sputtering target and the timing of replacement of the sputtering target.

In particular, the present disclosure has been made in an effort to accurately and visually detect the lifespan of the sputtering target and the timing of replacement of the sputtering target without using an expensive analysis device and to replace the sputtering target in a timely manner.

The present disclosure has also been made in an effort to improve the coating quality of a separator and minimize a coating defect.

Among other things, the present disclosure has been made in an effort to minimize the imbalance and defect of a coating layer caused by local consumption of the sputtering target.

The present disclosure has also been made in an effort to simplify a structure and a manufacturing process and reduce costs.

The objects to be achieved by the embodiments are not limited to the above-mentioned objects, but also include objects or effects that may be understood from the solutions or embodiments described below.

An exemplary embodiment of the present disclosure provides a separator processing device for an electrochemical apparatus, the separator processing device including: a vacuum chamber; a separator in the vacuum chamber; and a sputtering target in the vacuum chamber, the sputtering target including target elements and luminescent elements.

In the exemplary embodiment, the sputtering target may include a luminescent layer comprising the luminescent elements; and a target layer comprising the target elements, stacked on the luminescent layer, and facing the separator. The sputtering target may further include a base layer, and the luminescent layer may be stacked on the base layer.

In the exemplary embodiment, the separator processing device may further include a flow rate controller configured to adjust a supply flow rate of a reactant gas to be supplied into the vacuum chamber. The separator processing device may further include an ion beam, an electron beam, a magnetron, a thermal evaporator, an arc generator, or a combination thereof.

An exemplary embodiment of the present disclosure provides a separator processing device for an electrochemical apparatus, the separator processing device including: a vacuum chamber; a susceptor provided in the vacuum chamber and configured to allow a separator to be seated thereon; and a sputtering target provided on the vacuum chamber and including target elements and luminescent elements that are configured to be deposited on the separator.

According to the exemplary embodiment of the present disclosure, the sputtering target for an object may include: a base layer; a luminescent layer including the luminescent elements and stacked on the base layer; and a target layer including the target elements and stacked on the luminescent layer facing the object.

According to the exemplary embodiment of the present disclosure, the separator processing device may include: an insulator member interposed between the target layer and the vacuum chamber.

According to the exemplary embodiment of the present disclosure, an opening portion may be provided on one surface of the vacuum chamber facing the separator, and the sputtering target may be configured to cover the opening portion.

According to the exemplary embodiment of the present disclosure, the target element may include precious metal.

According to the exemplary embodiment of the present disclosure, the target element may include at least any one of platinum (Pt), iridium (Ir), and gold (Au).

According to the exemplary embodiment of the present disclosure, the luminescent element may include at least any one of an ultraviolet-sensitive material and colored metal.

In the exemplary embodiment, the separator processing device may further include a flow rate controller configured to adjust a supply flow rate of a reactant gas to be supplied into the vacuum chamber. The separator processing device may further include an ion beam, an electron beam, a magnetron, a thermal evaporator, an arc generator, or a combination thereof.

Another exemplary embodiment of the present disclosure provides a sputtering target for an object, the sputtering target including: a base layer; a luminescent layer including luminescent elements and stacked on the base layer; and a target layer including target elements and stacked on the luminescent layer facing the object.

According to the exemplary embodiment of the present disclosure, the target element may include precious metal.

According to the exemplary embodiment of the present disclosure, the target element may include at least any one of platinum (Pt), iridium (Ir), and gold (Au).

According to the exemplary embodiment of the present disclosure, the luminescent element may include at least any one of an ultraviolet-sensitive material and colored metal.

The ultraviolet-sensitive material may be at least any one of silver chloride (AgCl), bromide (AgBr), silver iodide (AgI), spirooxazines, spiropyrans, fulgides, benzophenone, zinc oxide, and titanium dioxide.

The colored material may include at least any one of lead (Pb), aluminum (Al), nickel (Ni), magnesium (Mg), tin (Sn), antimony (Sb), zinc (Zn), and titanium (Ti).

As discussed, the method and system suitably include use of a controller or processer.

### BRIEF DESCRIPTION OF THE DRAWINGS

FIG. 1 is a view for explaining a separator processing device for an electrochemical apparatus according to an exemplary embodiment of the present disclosure.

FIG. 2 is a view for explaining a sputtering target according to the embodiment of the present disclosure.

FIG. 3 is a view for explaining a sputtering process performed by the separator processing device for an electrochemical apparatus according to the embodiment of the present disclosure.

### DETAILED DESCRIPTION

Hereinafter, exemplary embodiments of the present disclosure will be described in detail with reference to the accompanying drawings.

However, the technical spirit of the present disclosure is not limited to some embodiments described herein but may be implemented in various different forms. One or more of the constituent elements in the embodiments may be selectively combined and substituted for use within the scope of the technical spirit of the present disclosure.

In addition, unless otherwise specifically and explicitly defined and stated, the terms (including technical and scientific terms) used in the embodiments of the present disclosure may be construed as the meaning which may be commonly understood by the person with ordinary skill in the art to which the present disclosure pertains. The meanings of the commonly used terms such as the terms defined in dictionaries may be interpreted in consideration of the contextual meanings of the related technology.

In addition, the terms used in the embodiments of the present disclosure are for explaining the embodiments, not for limiting the present disclosure.

In the present specification, unless particularly stated otherwise, a singular form may also include a plural form. The expression “at least one (or one or more) of A, B, and C” may include one or more of all combinations that can be made by combining A, B, and C.

In addition, the terms such as first, second, A, B, (a), and (b) may be used to describe constituent elements of the embodiments of the present disclosure.

These terms are used only for the purpose of discriminating one constituent element from another constituent element, and the nature, the sequences, or the orders of the constituent elements are not limited by the terms.

Further, when one constituent element is described as being ‘connected’, ‘coupled’, or ‘attached’ to another constituent element, one constituent element may be connected, coupled, or attached directly to another constituent element or connected, coupled, or attached to another constituent element through still another constituent element interposed therebetween.

In addition, the expression “one constituent element is provided or disposed above (on) or below (under) another constituent element” includes not only a case in which the two constituent elements are in direct contact with each other, but also a case in which one or more other constituent elements are provided or disposed between the two constituent elements. The expression “above (on) or below (under)” may mean a downward direction as well as an upward direction based on one constituent element.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

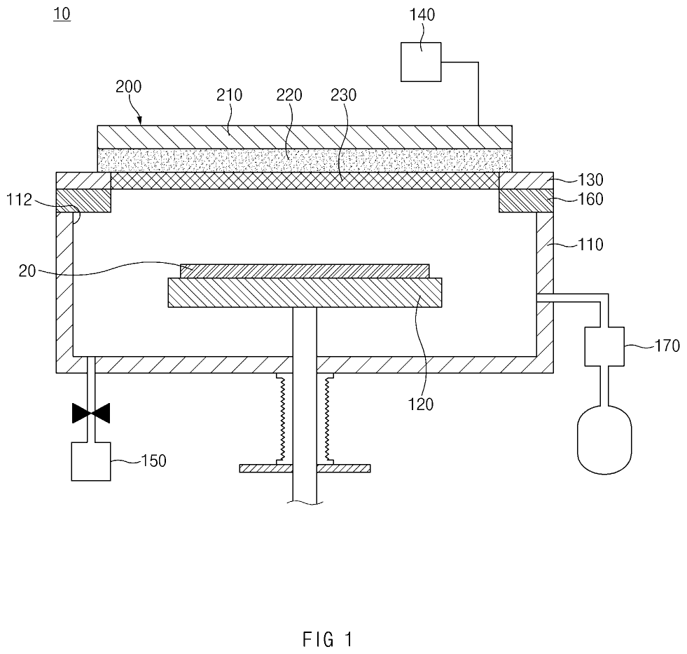

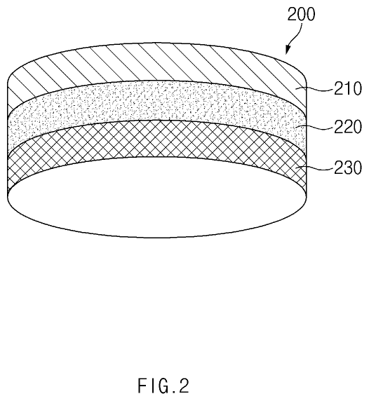

With reference to FIGS. 1 to 3, a separator processing device 10 for an electrochemical apparatus according to an exemplary embodiment of the present disclosure includes a vacuum chamber 110, a susceptor 120 provided in the vacuum chamber 110 and configured to allow a separator 20 to be seated thereon, and a sputtering target 200 provided on the vacuum chamber 110 and including target elements 232 and luminescent elements 222 which are configured to be deposited on the separator 20.

This may be to accurately detect the lifespan of the sputtering target 200 and the timing of replacement of the sputtering target 200 for coating the separator 20.

That is, the durability and conductivity of the separator 20 for an electrochemical apparatus need to be ensured to ensure the performance of the electrochemical apparatus. To this end, a coating layer (e.g., a precious metal coating layer) may be provided on a surface of the separator 20 by a deposition process (e.g., PVD) using the sputtering target 200.

Meanwhile, the sputtering target 200 may be made by stacking a target layer 230, which includes the target elements 232 (e.g., precious metal), on one surface of a base layer 210 including base elements (e.g., copper). When a thickness deviation of the target layer 230 is increased to a predetermined level or higher by the repeated deposition process using the sputtering target 200 or when the base layer 210 is exposed (e.g., locally exposed) by the consumption of the target layer 230, there occurs a problem in that it is difficult to entirely uniformly form a thickness of the coating layer, quality of the coating layer deteriorates, and a defect rate increases.

In particular, when the base layer 210 is exposed directly to the separator 20 because of the consumption of the target layer 230, the base elements constituting the base layer 210 are emitted as ions, which causes a problem with contaminating the separator 20.

However, in the related art, it is difficult for an operator to visually and directly detect the timing of replacement of the sputtering target 200 (the timing of a wear limit of the target layer 230), and an expensive analysis device inevitably needs to be used to detect the timing of replacement of the sputtering target 200, which causes a problem with degrading the process efficiency and increasing costs.

However, according to the embodiment of the present disclosure, the sputtering target 200 includes the target elements 232 and the luminescent elements 222, such that the operator may visually and directly identify the lifespan of the sputtering target 200 and the timing of replacement of the sputtering target 200 without using an expensive analysis device. Therefore, it is possible to obtain an advantageous effect of simply and accurately detecting the lifespan of the sputtering target 200 and the timing of replacement of the sputtering target 200.

In particular, according to the embodiment of the present disclosure, when the sputtering target 200 reaches the limit lifespan (a luminescent layer is exposed by the consumption of the target layer), the operator may visually and directly identify the lifespan of the sputtering target 200 and the timing of replacement of the sputtering target 200 by means of the luminescent elements 222 deposited on the separator 20. Therefore, it is possible to accurately detect the lifespan of the sputtering target 200 and replace the sputtering target 200 in a timely manner without performing a process of separating the sputtering target 200 from the vacuum chamber 110 and then performing a separate analysis process.

For reference, the separator processing device 10 for an electrochemical apparatus according to the embodiment of the present disclosure may be used to form a coating layer on a surface of the separator 20 for an electrochemical apparatus.

In this case, the electrochemical apparatus is defined as including both a water electrolysis stack configured to produce hydrogen and oxygen by electrochemically decomposing water and a fuel cell stack configured to generate electrical energy through a chemical reaction of fuel (e.g., hydrogen).

Hereinafter, an example will be described in which the separator processing device 10 for an electrochemical apparatus according to the embodiment of the present disclosure is used to form a coating layer on a surface of the separator 20 for a water electrolysis stack that produces hydrogen and oxygen by decomposing water through an electrochemical reaction.

For example, the water electrolysis stack (electrochemical apparatus) may be provided by stacking a plurality of unit cells in a reference stacking direction.

More specifically, the unit cell may include a reaction layer (not illustrated) and the separators 20 respectively stacked on one surface and the other surface of the reaction layer. The water electrolysis stack may be configured by stacking the plurality of unit cells in the reference stacking direction and then assembling endplates (not illustrated) to the two opposite ends of the plurality of unit cells.

The reaction layer may have various structures capable of causing the electrochemical reaction of a target fluid (e.g., water). The present disclosure is not restricted or limited by the type and structure of the reaction layer.

For example, the reaction layer may include a membrane electrode assembly (MEA) (not illustrated) and porous base layers provided to be in close contact with two opposite surfaces of the membrane electrode assembly (MEA).

The membrane electrode assembly may be variously changed in structure and material in accordance with required conditions and design specifications. The present disclosure is not restricted or limited by the structure and material of the membrane electrode assembly.

For example, the membrane electrode assembly may be configured by attaching catalyst electrode layers (e.g., an anode layer and a cathode layer), in which electrochemical reactions are generated, to two opposite surfaces of an electrolyte membrane (e.g., a perfluorinated sulfonic acid ionomer-based electrolyte membrane).

For reference, water supplied to the anode layer, which is an oxidation electrode for the water electrolysis, is separated into hydrogen ions (protons), electrons, and oxygen. Then, the hydrogen ions move to the cathode layer, which is a reduction electrode, through the electrolyte membrane, and the electrons move to a cathode through an external circuit. In addition, oxygen gas may be discharged to an anode outlet, and the hydrogen ions and electrons may be converted into hydrogen gas at a cathode and then the hydrogen gas may be discharged to a cathode outlet.

The separator 20, together with the reaction layer (membrane electrode assembly), may constitute a single unit cell (water electrolysis cell). The separator 20 may serve to separate and block water (or water and oxygen) at the anode side and hydrogen produced at the cathode side by the reaction layer. The separator 20 may also serve to ensure a flow path (flow field) of the fluid.

In addition, the separator 20 may also serve to distribute heat, which is generated from the unit cell to the entire unit cell, and the excessively generated heat may be discharged to the outside by water flowing along the separator 20.

For reference, in the embodiment of the present disclosure, the separators 20 are defined as including both an anode separator and a cathode separator that independently define the flow paths (channels) for water (or water and oxygen) and the flow paths (channels) for hydrogen in the water electrolysis stack.

For example, the separator (anode separator), which faces one surface of the membrane electrode assembly, may define a flow path (channel) for water (or water and oxygen). The separator (cathode separator), which faces the other surface of the membrane electrode assembly, may define a flow path (channel) for hydrogen.

The separator 20 may have various structures and be made of various materials in accordance with required conditions and design specifications. The present disclosure is not restricted or limited by the structure and material of the separator 20.

For example, the separator 20 may have an approximately quadrangular plate shape and be made of metal (e.g., titanium, stainless steel, Inconel, or aluminum).

According to another embodiment of the present disclosure, the separator may be provided in a circular shape or other shapes. The separator may be made of other materials such as graphite or a carbon composite.

The vacuum chamber 110 is configured to define a space (vacuum space) for forming the coating layer on the surface of the separator 20.

According to the exemplary embodiment of the present disclosure, the vacuum chamber 110 is configured to define a vacuum space for performing physical vapor deposition (PVD).

For reference, the physical vapor deposition (PVD) refers to a process of vaporizing a material (target element), which is intended to be deposited, in the vacuum chamber 110 and then depositing vaporized particles onto the separator 20.

The vacuum chamber 110 may have various structures having a predetermined processing space (vacuum space) therein. The present disclosure is not restricted or limited by the size and structure of the vacuum chamber 110.

For example, the vacuum chamber 110 may be provided in the form of an approximately quadrangular chamber having an opening portion 112 provided at an upper end (based on FIG. 1) thereof. An exit/entrance portion (not illustrated), through which the separator (object) 20 exits or enters the vacuum chamber 110, may be provided in a sidewall of the vacuum chamber 110.

For reference, in the present disclosure, the vacuum chamber 110 may be understood as a concept of a casing or container that may establish both an atmospheric pressure condition and a processing environment with a condition lower than the atmospheric pressure.

The vacuum chamber 110 may be made of various materials in accordance with required conditions and design specifications. For example, an inner wall of the vacuum chamber 110 may be made of a typical aluminum (Al) material.

The susceptor 120 may be provided in the vacuum chamber 110, and the separator 20 may be seated on a top surface of the susceptor 120.

The susceptor 120 may have various structures on which the separator 20 may be seated. The present disclosure is not restricted or limited by the structure and shape of the susceptor 120.

For example, the susceptor 120 may have an approximately circular plate shape. The susceptor 120 may be provided in the vacuum chamber 110 and configured to be movable upward or downward in an upward/downward direction. For example, the susceptor 120 may be moved in the upward/downward direction by a typical drive means such as a motor.

In addition, various types of accessory devices may be connected to the vacuum chamber 110. The accessory devices may include a vacuum pump 150 configured to maintain a vacuum in an internal space of the vacuum chamber 110, and a flow rate controller 170 configured to adjust a supply flow rate of a reactant gas (e.g., at least one of argon, nitrogen, helium, oxygen, and acetylene) to be supplied into the vacuum chamber 110. The present disclosure is not restricted or limited by the type and structure of the accessory device.

The sputtering target 200 includes the target elements 232 and the luminescent elements 222 and is provided on the vacuum chamber 110.

For reference, once the reactant gas is ionized by high energy electrons to sputter the target elements 232, the target elements 232 may be deposited on the separator 20 and configured to form the coating layer on the surface of the separator 20. In some embodiments, the reactant gas is ionized by, for example, an ion beam, an electron beam, a magnetron, a thermal evaporator, an arc generator, or a combination thereof.

Once a portion of the target elements 232 are sputtered and consumed such that the luminescent elements 222 are exposed (or to be exposed) to the ionized reactant gas to be sputtered, it would enable a user to determine the timing of replacement of the sputtering target 200 by inspecting or monitoring the coating layer on the surface of the separator 20, the sputtering target 200, and/or the vacuum chamber 110. The local sputtering and consummation of the target elements 232 may enable a user to determine the timing of replacement because of the exposed (or to be exposed) luminescent elements 222 on the sputtering target 200; the luminescent elements 222 already sputtered and deposited onto the surface of the separator 20; or the luminescent elements 222 sputtered and present in the vacuum chamber 110. This inspecting and monitoring process may be done visually, by instruments, or by any desired methods. Preferably, the inspecting and monitoring process may be done visually. Predefined luminescence or color level may be used to stop the sputtering process to minimize the contamination of the coating layer on the surface of the separator 20. For example, upon the inspection of the sputtering target 200, if the monitored luminescence or color level of the sputtering target 200 exceeds a predefined luminescence or color level, the sputtering process can be stopped manually or automatically. Similarly, upon the inspection of the sputtering target 200, if the monitored luminescence or color level of the surface of the separator 20 exceeds a predefined luminescence or color level, the sputtering process can be stopped manually or automatically. Similarly, upon the inspection of the vacuum chamber 110, if the monitored luminescence or color level of the surface of the vacuum chamber 110 exceeds a predefined luminescence or color level, the sputtering process can be stopped manually or automatically. In some embodiments, it may be possible to monitor more than one of the coating layer on the surface of the separator 20, the sputtering target 200, and/or the vacuum chamber 110 at the same time. For each inspection, a predefined luminescence or color level may vary or be the same.

The sputtering target 200 may be provided on the vacuum chamber 110 in various ways in accordance with required conditions and design specifications.

According to the exemplary embodiment of the present disclosure, the sputtering target 200 may be configured to cover the opening portion 112 of the vacuum chamber 110.

According to another embodiment of the present disclosure, the sputtering target may be provided on an inner wall surface of the vacuum chamber. Alternatively, the sputtering target may be disposed in the vacuum chamber by means of a separate support.

For reference, in the embodiment of the present disclosure, the example has been described in which the single sputtering target 200 is provided on the vacuum chamber 110. However, according to another embodiment of the present disclosure, two or more sputtering targets may be provided on the vacuum chamber.

The sputtering target 200 may have various structures including the target elements 232 and the luminescent elements 222. The present disclosure is not restricted or limited by the structure of the sputtering target 200.

In particular, the sputtering target 200 may have a structure in which the luminescent elements 222 may be exposed after the target elements 232 are consumed to a predetermined level or higher.

According to the exemplary embodiment of the present disclosure, the sputtering target 200 may include the base layer 210, a luminescent layer 220 including the luminescent elements 222 and stacked on one surface of the base layer 210, and the target layer 230 including the target elements 232 and stacked on one surface of the luminescent layer 220 while facing the separator 20.

The base layer 210 serves to support the luminescent layer 220 and the target layer 230, cool the sputtering target 200, and transmit electric power.

The base layer 210 may be made of various materials and have various structures in accordance with required conditions and design specifications. The present disclosure is not restricted or limited by the structure and material of the base layer 210.

For example, the base layer 210 may have an approximately circular plate shape and be made of copper.

Further, a power supply 140 for applying power may be electrically connected to the base layer 210. For example, at least any one of direct current power and alternating current power may be applied to the base layer 210 by means of the power supply 140.

The luminescent layer 220 includes the luminescent element 222 and is stacked on one surface (a bottom surface based on FIG. 1) of the base layer 210 facing the separator 20.

The luminescent layer 220 may have various structures in accordance with required conditions and design specifications. The present disclosure is not restricted or limited by the structure of the luminescent layer 220.

For example, the luminescent layer 220 may have an approximately circular plate shape corresponding to the base layer 210.

Various materials, which may be visually and directly identified by the operator, may be used as the luminescent element 222. The present disclosure is not restricted or limited by the type and properties of the luminescent element 222.

According to the exemplary embodiment of the present disclosure, the luminescent element 222 may include at least any one of an ultraviolet-sensitive material and colored metal.

In the embodiment of the present disclosure, the ultraviolet-sensitive material may be defined as a material that chemically changes or reacts when exposed to ultraviolet rays.

Various materials, which chemically change or react when exposed to ultraviolet rays, may be used as the ultraviolet-sensitive material. The present disclosure is not restricted or limited by the type and properties of the ultraviolet-sensitive material.

For example, at least any one of silver chloride (AgCl), silver bromide (AgBr), silver iodide (AgI), spirooxazines, spiropyrans, fulgides, benzophenone, zinc oxide, and titanium dioxide may be used as the ultraviolet-sensitive material.

In addition, in the embodiment of the present disclosure, colored metal may be defined as metal having a color, other than iron and iron alloys. The present disclosure is not restricted or limited by the type and properties of colored metal.

For example, at least any one of lead (Pb), aluminum (Al), nickel (Ni), magnesium (Mg), tin (Sn), antimony (Sb), zinc (Zn), and titanium (Ti) may be used as colored metal.

The target layer 230 includes the target element 232 and is stacked on one surface (a bottom surface based on FIG. 1) of the luminescent layer 220 facing the separator 20.

The target layer 230 may have various structures in accordance with required conditions and design specifications. The present disclosure is not restricted or limited by the structure of the target layer 230.

For example, the target layer 230 may have an approximately circular plate shape corresponding to the luminescent layer 220.

Various materials may be used as the target element 232 in accordance with required conditions and design specifications. The present disclosure is not restricted or limited by the type and properties of the target element 232.

According to the exemplary embodiment of the present disclosure, typical precious metal may be used as the target element 232.

According to the exemplary embodiment of the present disclosure, the target element 232 may include at least any one of platinum (Pt), iridium (Ir), and gold (Au).

According to the exemplary embodiment of the present disclosure, the separator processing device 10 for an electrochemical apparatus may include an insulator member 130 interposed between the target layer 230 and the vacuum chamber 110.

The insulator member 130 may be configured to electrically insulate (isolate) the vacuum chamber 110 and the target layer 230. The present disclosure is not restricted or limited by the structure and material of the insulator member 130.

For example, the insulator member 130 may have a continuous ring shape. The insulator member 130 may be mounted on the vacuum chamber 110 by means of an adapter 160 provided at an upper end (based on FIG. 1) of the vacuum chamber 110.

In the illustrated and aforementioned embodiment, the example has been described in which the insulator member 130 is mounted on the vacuum chamber 110 by means of the adapter 160. However, according to another embodiment of the present disclosure, the insulator member may be mounted directly on the vacuum chamber without a separate adapter.

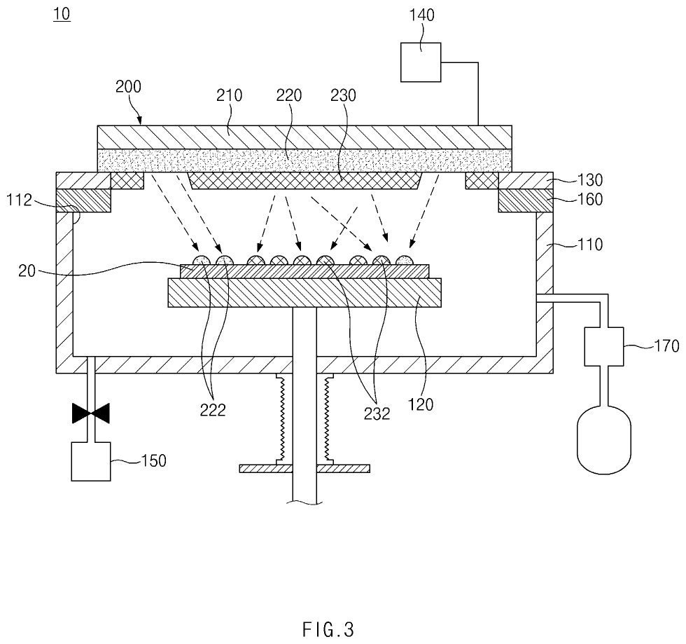

With the above-mentioned configuration, as illustrated in FIG. 3, the luminescent layer 220 may be exposed to the outside of the target layer 230 when the sputtering target 200 reaches the limit lifespan as the deposition process using the sputtering target 200 is repeatedly performed. The luminescent elements 222 may be deposited on the surface of the separator 20 from the luminescent layer 220 exposed to the outside of the target layer 230.

Therefore, the operator may simply and accurately detect the lifespan of the sputtering target 200 and the timing of replacement of the sputtering target 200 without using an expensive analysis device by visually identifying whether the luminescent element is exposed from the sputtering target 200 or visually identifying the luminescent element 222 deposited on the separator 20.

According to the embodiment of the present disclosure described above, it is possible to obtain an advantageous effect of improving the stability and reliability and accurately detecting the lifespan of the sputtering target and the timing of replacement of the sputtering target.

In particular, according to the embodiment of the present disclosure, the operator may visually and directly identify the lifespan of the sputtering target and the timing of replacement of the sputtering target without using an expensive analysis device. Therefore, the operator may accurately detect the lifespan of the sputtering target and the timing of replacement of the sputtering target and replace the sputtering target in a timely manner.

In addition, according to the embodiment of the present disclosure, it is possible to obtain an advantageous effect of improving the coating quality of the separator and minimizing a coating defect.

Among other things, according to the embodiment of the present disclosure, it is possible to obtain an advantageous effect of minimizing the imbalance and defect of a coating layer caused by local consumption of the sputtering target.

In addition, according to the embodiment of the present disclosure, it is possible to obtain an advantageous effect of simplifying the structure and the manufacturing process and reducing the costs.

While the embodiments have been described above, the embodiments are just illustrative and not intended to limit the present disclosure. It can be appreciated by those skilled in the art that various modifications and applications, which are not described above, may be made to the present embodiment without departing from the intrinsic features of the present embodiment. For example, the respective constituent elements specifically described in the embodiments may be modified and then carried out. Further, it should be interpreted that the differences related to the modifications and applications are included in the scope of the present disclosure defined by the appended claims.

What is claimed is:

1. A separator processing device for an electrochemical apparatus, the separator processing device comprising:
a vacuum chamber;
a separator in the vacuum chamber; and
a sputtering target in the vacuum chamber, the sputtering target comprising target elements and luminescent elements.

2. The separator processing device of claim 1, wherein the sputtering target comprises:
a luminescent layer comprising the luminescent elements; and
a target layer comprising the target elements, stacked on the luminescent layer, and facing the separator.

3. The separator processing device of claim 2, wherein the sputtering target further comprises a base layer, and wherein the luminescent layer is stacked on the base layer.

4. The separator processing device of claim 1, further comprising a flow rate controller configured to adjust a supply flow rate of a reactant gas to be supplied into the vacuum chamber.

5. The separator processing device of claim 4, further comprising an ion beam, an electron beam, a magnetron, a thermal evaporator, an arc generator, or a combination thereof.

6. A separator processing device for an electrochemical apparatus, the separator processing device comprising:
a vacuum chamber;
a susceptor provided in the vacuum chamber and configured to allow a separator to be seated thereon; and
a sputtering target provided on the vacuum chamber and comprising target elements and luminescent elements that are configured to be deposited on the separator.

7. The separator processing device of claim 6, wherein the sputtering target comprises:
a base layer;
a luminescent layer comprising the luminescent elements and stacked on the base layer; and
a target layer comprising the target elements, stacked on the luminescent layer, and facing the separator.

8. The separator processing device of claim 7, comprising:
an insulator member interposed between the target layer and the vacuum chamber.

9. The separator processing device of claim 6, wherein an opening portion is provided on one surface of the vacuum chamber facing the separator, and the sputtering target is configured to cover the opening portion.

10. The separator processing device of claim 6, wherein the target element comprises precious metal.

11. The separator processing device of claim 6, wherein the target element comprises at least any one of platinum (Pt), iridium (Ir), and gold (Au).

12. The separator processing device of claim 6, wherein the luminescent element comprises at least any one of an ultraviolet-sensitive material and colored metal.

13. The separator processing device of claim 6, further comprising a flow rate controller configured to adjust a supply flow rate of a reactant gas to be supplied into the vacuum chamber.

14. The separator processing device of claim 6, further comprising an ion beam, an electron beam, a magnetron, a thermal evaporator, an arc generator, or a combination thereof.

15. A sputtering target for an object, the sputtering target comprising:
a base layer;
a luminescent layer comprising luminescent elements and stacked on the base layer; and
a target layer comprising target elements and stacked on the luminescent layer facing the object.

16. The sputtering target of claim 15, wherein the target element comprises precious metal.

17. The sputtering target of claim 15, wherein the target element comprises at least any one of platinum (Pt), iridium (Ir), and gold (Au).

18. The sputtering target of claim 15, wherein the luminescent element comprises at least any one of an ultraviolet-sensitive material and colored metal.

19. The sputtering target of claim 18, wherein the ultraviolet-sensitive material comprises at least any one of silver chloride (AgCl), silver bromide (AgBr), silver iodide (AgI), spirooxazines, spiropyrans, fulgides, benzophenone, zinc oxide, and titanium dioxide.

20. The sputtering target of claim 18, wherein the colored material comprises at least any one of lead (Pb), aluminum (Al), nickel (Ni), magnesium (Mg), tin (Sn), antimony (Sb), zinc (Zn), and titanium (Ti).
